(19) United States
(12) Patent Application Publication
(10) Pub. No.: US 2013/0221398 A1
(43) Pub. Date: Aug. 29, 2013

(54) SEMICONDUCTOR LIGHT EMITTING DEVICE AND FABRICATION METHOD THEREOF

(71) Applicant: SAMSUNG ELECTRONICS CO., LTD., (US)

(72) Inventors: Bum Joon Kim, Seoul (KR); Young Sun Kim, Gyeonggi-do (KR); Suk Ho Yoon, Seoul (KR); Ki Sung Kim, Gyeonggi-do (KR); Dong Chul Shin, Gyeongsangnam-do (KR)

(73) Assignee: SAMSUNG ELECTRONICS CO., LTD., Gyeonggi-do (KR)

(21) Appl. No.: 13/774,376

(22) Filed: Feb. 22, 2013

(30) Foreign Application Priority Data
Feb. 24, 2012 (KR) 10-2012-0018964

(51) Int. Cl. H01L 33/62

(52) U.S. Cl. CPC H01L 33/62
USPC 257/99; 438/45

(57) ABSTRACT

A semiconductor light emitting device includes a conductive substrate, a light emitting structure, a first contact layer, a conductive via and a current interruption region. The light emitting structure is disposed on the conductive substrate and includes a first conductive semiconductor layer, an active layer, and a second conductive semiconductor layer. The first contact layer is disposed between the conductive substrate and the first conductive semiconductor layer. The conductive via is disposed to extend from the conductive substrate to be connected to the second conductive semiconductor layer. The current interruption region is disposed in a region adjacent to the conductive via in the light emitting structure.

### CROSS-REFERENCE TO RELATED APPLICATION

This application claims benefit of priority to Korean Patent Application No. 10-2012-0018964 filed on Feb. 24, 2012, in the Korean Intellectual Property Office, the entire contents of which are hereby incorporated by reference.

### TECHNICAL FIELD

The present inventive concept relates to a semiconductor light emitting device and a fabrication method thereof.

### BACKGROUND

In general, a nitride semiconductor has been widely used in a green or blue light emitting diode (LED) or a laser diode provided as a light source of a full-color display, an image scanner, various signal systems, or an optical communication device. A nitride semiconductor light emitting device may be provided as a light emitting device having an active layer emitting light of various colors, including blue and green, through the recombination of electrons and holes.

Such nitride light emitting devices have made remarkable progress since their first developments, having greatly expanded utilization. Research on utilizing nitride light emitting devices for general illumination devices, as well as light sources of electrical devices, has been actively conducted. In particular, as related art, nitride semiconductor light emitting devices have been largely used as components of low-current/low output mobile products. Recently, as the utilization of light emitting devices has extended into the field of high current/high output devices, research on improving the luminous efficiency and quality of semiconductor light emitting devices is actively under way. In particular, light emitting devices having various electrode structures have been developed for improved light outputs. Especially, research on increasing current spreading efficiency in light emitting devices is under way.

### SUMMARY

An aspect of the present inventive concept relates to a semiconductor light emitting device having an increased current spreading effect and enhanced light output.

An aspect of the present inventive concept encompasses a method of fabricating a semiconductor light emitting device allowing for the fabrication of a semiconductor light emitting device having enhanced light uniformity and light output through a simple process.

An aspect of the present inventive concept relates to a semiconductor light emitting device. The device includes a conductive substrate, and a light emitting structure disposed on the conductive substrate and including a first conductive semiconductor layer, an active layer, and a second conductive semiconductor layer. A first contact layer is disposed between the conductive substrate and the first conductive semiconductor layer. A conductive via is disposed to extend from the conductive substrate and penetrating the first contact layer, the first conductive semiconductor layer, and the active layer so as to be connected to the second conductive semiconductor layer. A current interruption region is disposed in a region adjacent to the conductive via in the light emitting structure.

The current interruption region may be disposed in at least one of the first and second conductive semiconductor layers of the light emitting structure.

The current interruption region may be an insulating region including an oxidized portion of at least one of the first and second conductive semiconductor layers.

The current interruption region may be an insulating region including an ion implanted portion of at least one of the first and second conductive semiconductor layers.

At least one of the first and second conductive semiconductor layers may include an AlₓIn_{y}Ga_{z}N layer (0<x≦1, 0≦y≦1, 0≦z≦1).

The current interruption region may be made of AlInON.

The current interruption region may be disposed in at least a portion of an area surrounding the conductive via.

The semiconductor light emitting device may further include an insulator to electrically separate the conductive substrate from the first contact layer, the first conductive semiconductor layer, and the active layer.

A lateral side of the light emitting structure may be sloped.

The conductive via may be connected to the second conductive semiconductor layer.

An aspect of the present inventive concept relates to a method of fabricating a semiconductor light emitting device, including: forming a light emitting structure by sequentially growing a second conductive semiconductor layer, an active layer, and a first conductive semiconductor layer on a semiconductor growth substrate; forming a current interruption region in a portion in the light emitting structure; forming a recess penetrating the first conductive semiconductor layer and the active layer and exposing the second conductive semiconductor layer; forming a first contact layer on the light emitting structure; forming an insulator to cover an upper portion of the first contact layer and a side wall of the recess; forming a conductive material within the recess and on the insulator to form a conductive via connected to the second conductive semiconductor layer; forming a conductive substrate on the insulator such that the conductive substrate is connected to the conductive via; and removing the semiconductor growth substrate from the light emitting structure.

The current interruption region may be formed in at least one of the first and second conductive semiconductor layers of the light emitting structure.

The current interruption region may be formed by oxidizing a portion of at least one of the first and second conductive semiconductor layers.

The current interruption region may be formed in a portion adjacent to the conductive via.

The current interruption region may be formed by performing ion implantation.

Another aspect of the present inventive concept relates to a semiconductor light emitting device. The device includes a conductive substrate, and a light emitting structure disposed on the conductive substrate and including a first conductive semiconductor layer, an active layer, and a second conductive semiconductor layer. A first contact layer and a second contact layer are disposed between the conductive substrate and the first conductive semiconductor layer. A conductive via is disposed to extend from the second contact layer and penetrating the first contact layer, the first conductive semiconductor layer, and the active layer so as to be connected to the second conductive semiconductor layer. A current interruption region is disposed in a region adjacent to the conductive via in the light emitting structure.

The second contact layer and the conductive via may be electrically separated from the active layer, the first conductive semiconductor layer, the first contact layer, and the conductive substrate.

### BRIEF DESCRIPTION OF THE DRAWINGS

The foregoing and other features of the inventive concept will be apparent from more particular description of embodiments of the inventive concept, as illustrated in the accompanying drawings in which like reference characters may refer to the same or similar parts throughout the different views. The drawings are not necessarily to scale, emphasis instead being placed upon illustrating the principles of the embodiments of the inventive concept. In the drawings, the thickness of layers and regions may be exaggerated for clarity.

FIG. 1 is a cross-sectional view illustrating a section of a semiconductor light emitting device according to an embodiment of the present inventive concept.

FIG. 2 is a schematic top view of the semiconductor light emitting device illustrated in FIG. 1.

FIG. 3 is a schematic view illustrating a cross-section of a semiconductor light emitting device according to a modification of the embodiment of the present inventive concept illustrated in FIG. 1.

FIG. 4 is a schematic top view of the semiconductor light emitting device illustrated in FIG. 3.

FIG. 5 is a perspective view illustrating a cross-section of a semiconductor light emitting device according to an embodiment of the present inventive concept.

FIG. 6 is a perspective view illustrating a cross-section of a semiconductor light emitting device according to an embodiment of the present inventive concept.

FIG. 7 is a schematic view illustrating a cross-section of a semiconductor light emitting device according to a modification of the embodiment of the present inventive concept illustrated in FIG. 6.

FIGS. 8A to 8G are cross-sectional views sequentially illustrating a method of fabricating a semiconductor light emitting device according to an embodiment of the present inventive concept.

FIGS. 9A to 9F are cross-sectional views sequentially illustrating a method of fabricating a semiconductor light emitting device according to an embodiment of the present inventive concept.

### DETAILED DESCRIPTION OF THE PREFERRED EMBODIMENT

Examples of the present inventive concept will be described below in more detail with reference to the accompanying drawings. The examples of the present inventive concept may, however, be embodied in different forms and should not be construed as limited to the examples set forth herein. Like reference numerals may refer to like elements throughout the specification.

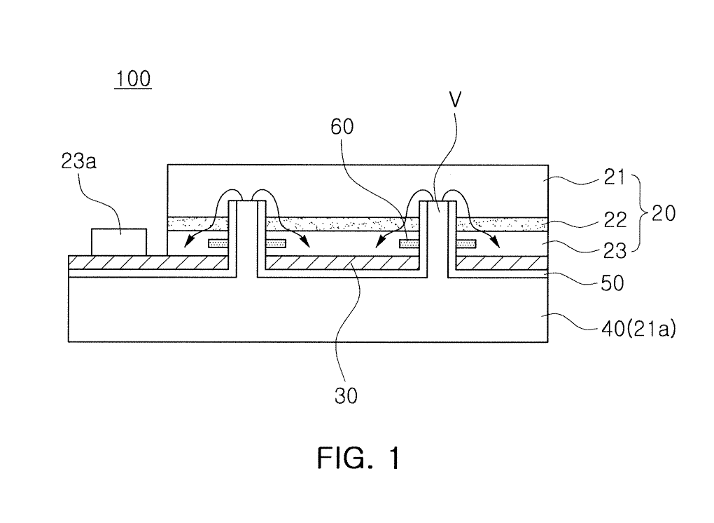

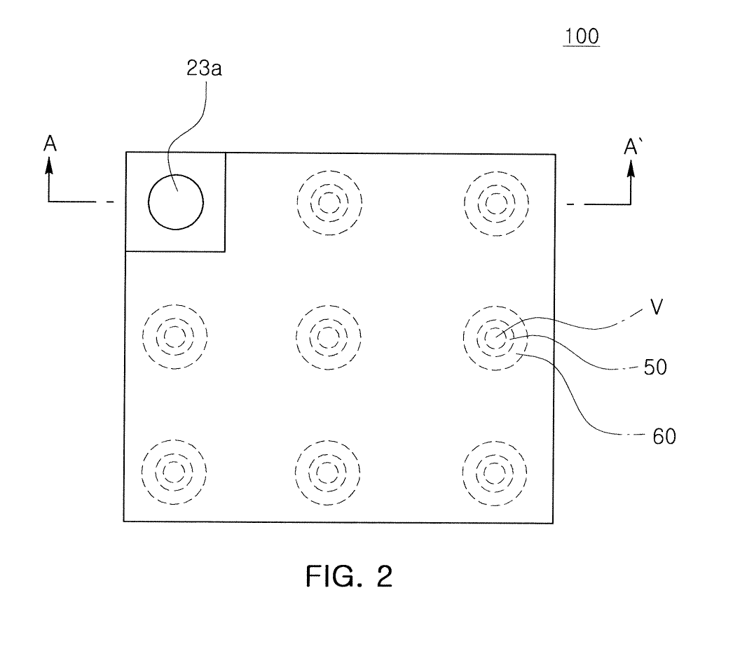

FIG. 1 is a cross-sectional view illustrating a section of a semiconductor light emitting device according to an embodiment of the present inventive concept. FIG. 2 is a schematic top view of the semiconductor light emitting device illustrated in FIG. 1. In detail, FIG. 1 is a cross-sectional view taken along line A-A′ in FIG. 2.

With reference to FIGS. 1 and 2, in a semiconductor light emitting device 100 according to an embodiment of the present inventive concept, a first contact layer 30 is formed on a conductive substrate 40. A light emitting structure 20 including a first conductive semiconductor layer 23, an active layer 22, and a second conductive semiconductor layer 21, is formed on the first contact layer 30. A conductive via V may be formed on the conductive substrate 40 and extend from the conductive substrate 40, penetrating the first contact layer 30, the first conductive semiconductor layer 23, and the active layer 22, so as to be connected to the second conductive semiconductor layer 21. A current interruption region 60 may be formed to be adjacent to the conductive via V in the light emitting structure 20. The first contact layer 30 is electrically separated from the conductive substrate 40. An insulator 50 may be interposed between the first contact layer 30 and the conductive substrate 40 in order to electrically separate them.

In an embodiment of the present inventive concept, the first and second conductive semiconductor layers 23 and may be p-type and n-type semiconductor layers, respectively, and may be made of a nitride semiconductor. Thus, in an embodiment of the present inventive concept, the first and second conductivity-types may be understood to indicate p-type and n-type conductivities, respectively, but the present inventive concept is not limited thereto. The first and second conductive semiconductor layers 23 and 21 may be made of a material expressed by an empirical formula AₗₓI_{ny}G_{a(1-x-y)}N (here, 0≦x≦1, 0≦y≦1, 0≦x+y≦1), and such a material may be GaN, AlGaN, InGaN, or the like.

The active layer 22 disposed between the first and second conductive semiconductor layers 23 and 21 emits light having a certain level of energy according to electron and hole recombination. The active layer 22 may have a multi-quantum well (MQW) structure in which a quantum well and a quantum barrier are alternately stacked. Here, the MQW structure may be, for example, an InGaN/GaN structure.

The first contact layer 30 may serve to reflect light emitted from the active layer 22 toward an upper portion of the semiconductor light emitting device 100, for example, toward the second conductive semiconductor layer 21. The first contact layer 30 may make ohmic-contact with the first conductive semiconductor layer 23. In realizing this function, the first contact layer 30 may include a material such as Ag, Ni, Al, Rh, Pd, Ir, Ru, Mg, Zn, Pt, Au, or the like. In this case, although not shown in detail, the first contact layer 30 may have a structure including two or more layers to improve reflection efficiency. For example, the structure having two or more layers of the first contact layer 30 may include Ni/Ag, Zn/Ag, Ni/Al, Zn/Al, Pd/Ag, Pd/Al, Ir/Ag, Ir/Au, Pt/Ag, Pt/Al, Ni/Ag/Pt, and the like.

In an embodiment of the present inventive concept, a region of the first contact layer 30 may be exposed, and as illustrated in FIG. 1, the exposed region may be a region in which the light emitting structure is not formed. The exposed region of the first contact layer 30 may correspond to an electrical connection portion for applying an electrical signal. Referring to FIG. 1, an electrode pad 23a may be formed on the exposed region of the first contact layer 30.

The conductive substrate 40 may serve as a support structure supporting the light emitting structure during a process such as laser lift-off, or the like, as explained hereinafter. The conductive substrate 40 may be made of a material including one or more selected from the group consisting of Au, Ni, Al, Cu, W, Si, Se, and GaAs, for example, a material in the form of silicon (Si) doped with aluminum (Al). In this case, the conductive substrate 40 may be formed through a method such as plating, bonding, or the like, according to a selected material.

In an embodiment of the present inventive concept, the conductive substrate 40 may be electrically connected to the second conductive semiconductor layer 21, and thus, the conductive substrate 40 may serve as a second electrode 21a (see FIG. 1) that applies an electrical signal to the second conductive semiconductor layer 21 through the conductive substrate 40. To this end, as shown in FIGS. 1 and 2, the conductive via V may be provided to extend from the conductive substrate 40 so as to be connected to the second conductive semiconductor layer 21.

The conductive via V is connected to the second conductive semiconductor layer 21. As contact resistance is lowered, the number, shape and pitch of the conductive via V, a contact area of the conductive via V with the second conductive semiconductor layer 21, and the like, may be appropriately adjusted. In an embodiment of the present inventive concept, the conductive via V is connected to the second conductive semiconductor layer 21 within the second conductive semiconductor layer 21, but according to another embodiment of the present inventive concept, the conductive via V may be formed to be connected to a surface of the second conductive semiconductor layer 21.

The conductive via V may be electrically separated from the active layer 22, the first conductive semiconductor layer 23, and the first contact layer 30. Thus, the insulator 50 may be formed between the conductive via V and other layers including the active layer 22, the first conductive semiconductor layer 23, and the first contact layer 30. The insulator 50 may be made of any material so long as it has electrical insulation characteristics, and in this case, a material which absorbs as little light as possible may be used. Thus, for example, silicon or silicon nitride such as SiO₂, SiOₓN_{Y}, or SiₓN_{y} may be used as a material of the insulator 50.

As described above, in an embodiment of the present inventive concept, the conductive substrate 40 is connected to the second conductive semiconductor layer 21 by the conductive via V, and there is no need to additionally form an electrode on an upper surface of the second conductive semiconductor layer 21. Thus, the amount of light emitted to the upper surface of the second conductive semiconductor layer 21 can be increased. In this case, although the light emitting region is reduced because of the presence of the conductive via V formed at portions of the active layer 22, the effect of enhancing light extraction efficiency, which can be obtained by omitting a formation of an electrode on an upper surface of the second conductive semiconductor layer 21, is rather greater.

Meanwhile, in the semiconductor light emitting device 100, an electrode is not disposed on the upper surface of the second conductive semiconductor layer 21. Thus, the overall electrode disposition is considered to be similar to a horizontal electrode structure, rather than to a vertical electrode structure. However, a sufficient current spreading effect is guaranteed by the presence of the conductive via V formed within the second conductive semiconductor layer 21.

The current interruption region 60 may be formed in at least a portion of an area surrounding the conductive via V in the light emitting structure 20, specifically, in at least one of the first and second conductive semiconductor layers 23 and 21. The current interruption region 60, being an insulating region having high resistance, expands a current flow in a horizontal direction to increase current spreading efficiency.

When the via V is formed to penetrate the interior of the light emitting structure 20, current is concentrated in the vicinity of the conductive via V, degrading light uniformity. However, in an embodiment of the present inventive concept, since the current interruption region 60 is formed adjacent to a conductive via V, current flow can be induced in the lateral direction as indicated by the arrows in FIG. 1, and accordingly, uniform luminance can be obtained from the entire surface of the light emitting device 100.

In an embodiment of the present inventive concept, the current interruption region 60 is illustrated as being formed within the first conductive semiconductor layer 23, but the present inventive concept is not limited thereto; the current interruption region 60 may be formed in at least one of the first and second conductive semiconductor layers 23 and 21. Also, as shown in FIG. 2, the current interruption region 60 may be formed in at least one portion of the lateral surface of the conductive via V. The current interruption region 60 may be variably modified to have a specific shape as necessary.

Meanwhile, the current interruption region 60 may be configured as an insulating region by oxidizing portions of the first and second conductive semiconductor layers 23 and 21 or implanting ions in the first and second conductive semiconductor layers 23 and 21.

In detail, the first and second conductive semiconductor layers 23 and 21 may include a nitride-based semiconductor including AlₓIn_{y}Ga_{(1-x-y)}N (0<x≦1, 0≦y≦1, 0≦x+y≦1), for example, aluminum (Al), and in this case, the current interruption region 60 may be made of AlInON formed as aluminum (Al) is oxidized. Alternatively, ion-implantable elements such as H, 2H, 3H, He, N, C, Ar, Zn, P, Ti, Zn, or the like, are ion-implanted in at least one of the first and second conductive semiconductor layers 23 and 21 to form the current interruption region 60 as an insulating region therein.

For example, in an embodiment of the present inventive concept, during the process of fabricating the semiconductor light emitting device, the current interruption region 60 is formed as an insulating region within the semiconductor layers by using a simple process such as semiconductor oxidization or ion implantation, thereby providing a semiconductor light emitting device having increased current spreading effects and enhanced light output.

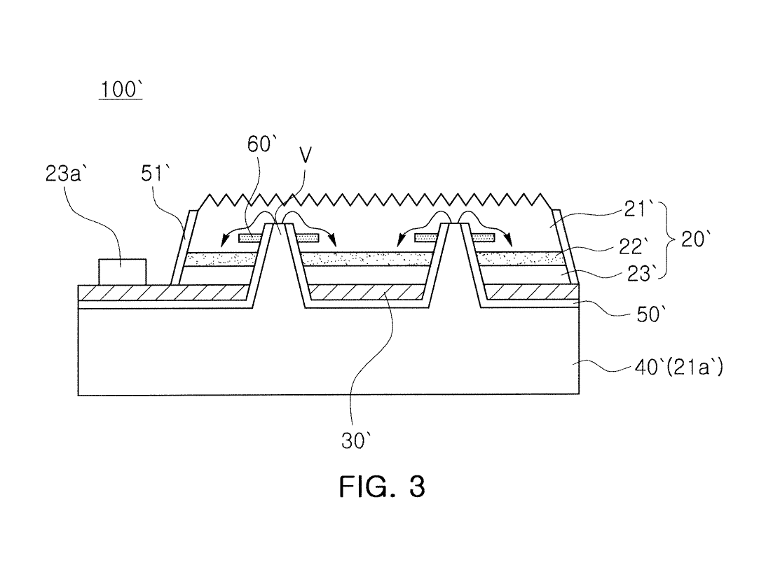

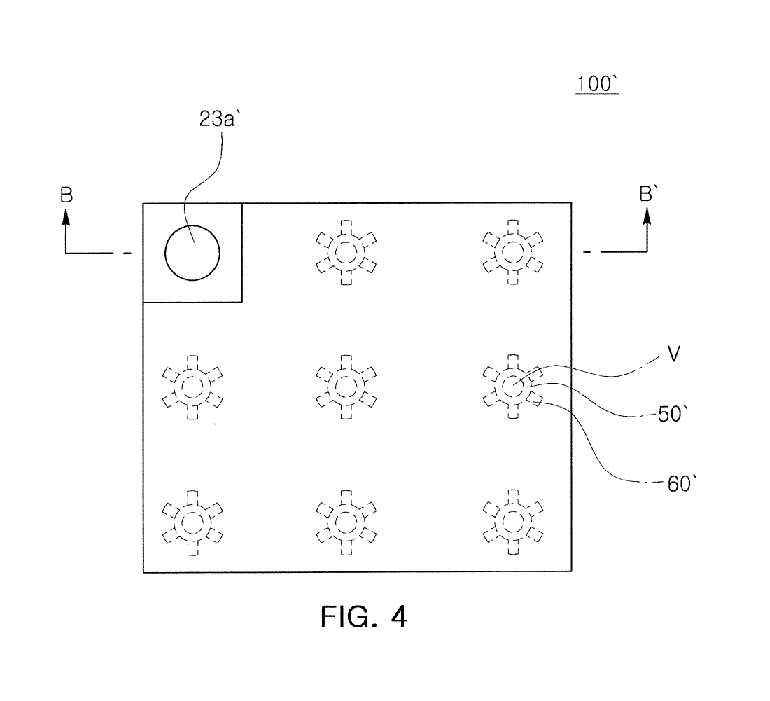

FIG. 3 is a schematic view illustrating a section of a semiconductor light emitting device according to a modification of the embodiment of the present inventive concept illustrated in FIGS. 1 and 2. FIG. 4 is a schematic top view of the semiconductor light emitting device illustrated in FIG. 3. Specifically, FIG. 3 is a sectional view taken along line B-B′ of the semiconductor light emitting device 100′ illustrated in FIG. 4.

With reference to FIGS. 3 and 4, the semiconductor light emitting device 100′ according to an embodiment of the present inventive concept may include a first contact layer 30′ and a light emitting structure 20′ formed on a conductive substrate 40′, and a conductive via V extending from the conductive substrate 40′ and penetrating a first conductive semiconductor layer 23′ and an active layer 22′, so as to be connected to a second conductive semiconductor layer 21′.

A current interruption region 60′ may be formed in the second conductive semiconductor layer 21′ adjacent to the conductive via V. An insulator 50′ may be further provided to electrically separate the conductive substrate 40′ and the conductive via V from other layers including the first contact layer 30′, the first conductive semiconductor layer 23′, and the active layer 22′ may be further provided.

Unlike the semiconductor light emitting device 100 illustrated in FIG. 1, in the semiconductor light emitting device 100′ according to an embodiment of the present inventive concept, the current interruption region 60′ is formed in the second conductive semiconductor layer 21′. The light emitting structure 20′ and the conductive via V have slightly different shapes from those of the semiconductor light emitting device 100 illustrated in FIG. 1. Hereinafter, a description of the same configurations will be omitted and only different configurations will be described.

First, with reference to FIG. 3, a lateral side of the light emitting structure 20′ may be sloped with respect to the first contact layer 30′. Specifically, the light emitting structure 20′ may be formed to have a width narrowed upwardly. Such a configuration may be naturally formed through a process of etching the light emitting structure 20′ to expose a portion of the first contact layer 30′.

The conductive via V may be formed to penetrate the first contact layer 30′, the first conductive semiconductor layer 23′, and the active layer 22′, so as to be connected to the second conductive semiconductor layer 21′. As illustrated in FIG. 3, the conductive via V may be formed to have a width narrowed upwardly. In this case, light emitted from the active layer 22′ of the light emitting structure 20′ is reflected from the lateral surface of the conductive via V and induced upwardly, thus enhancing light extraction efficiency.

Meanwhile, as shown in FIG. 3, a passivation layer 51′ may be formed to cover the lateral surface of the light emitting structure 20′. The passivation layer 51′ serves to protect the light emitting structure 20′, especially, the active layer 22′, against the surrounding environment. The passivation layer 51′ may be made of a silicon oxide or a silicon nitride such as SiO₂, SiOₓN_{y}, SiₓN_{y}, or the like and may have a thickness ranging from about 0.1 μm to 2 μm. A problem may occur when the active layer 22′ exposed to the outside serves as a current leakage path during an operation of the semiconductor light emitting device 100′. This problem may be solved by forming the passivation layer 51′.

Depressions and protrusions may be formed on the second conductive semiconductor layer 21′. The depressions and protrusions may increase a ratio of light generated from the active layer 22′, to light from the outside to enhance light extraction efficiency. As illustrated in FIG. 3, the depressions and protrusions may be formed on a surface of the second conductive semiconductor layer 21′ exposed as a semiconductor growth substrate (not separately shown) is removed. Although not separately shown, a buffer layer made of an undoped semiconductor may be formed between the semiconductor growth substrate and the light emitting structure 20′.

Unlike the current interruption layer 60 of the embodiment illustrated in FIG. 1, the current interruption layer 60′ may be formed in the second conductive semiconductor layer 21′. Although not separately shown, the current interruption layer 60′ may be formed in both of the first and second conductive semiconductor layers 23′ and 21′. Also, as illustrated in FIG. 4, the current interruption layer 60′ may be formed only in a region adjacent to the conductive via V. For example, the current interruption layer 60′ may form a certain pattern as necessary and may only be formed in a region adjacent to the conductive via V.

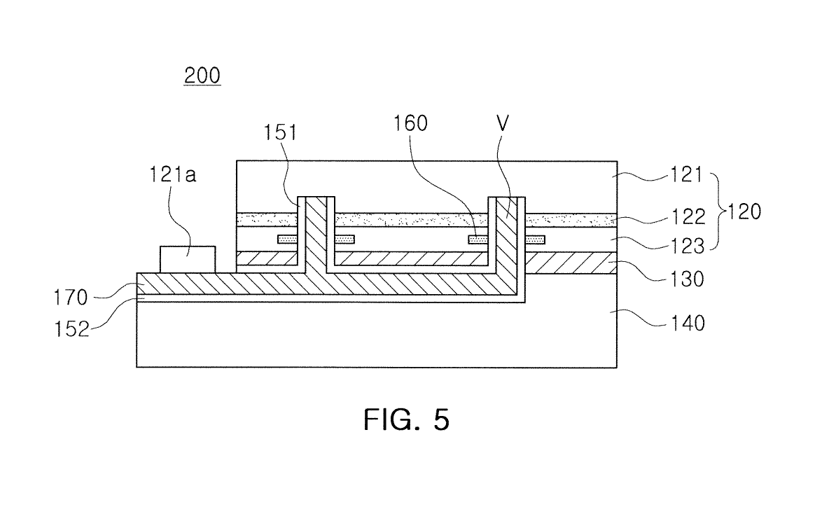

FIG. 5 is a perspective view illustrating a section of a semiconductor light emitting device according to an embodiment of the present inventive concept.

With reference to FIG. 5, in a semiconductor light emitting device 200 according to an embodiment of the present inventive concept, a light emitting structure 120 may be formed on a conductive substrate 140 and include a first conductive semiconductor layer 123, an active layer 122, and a second conductivity-type semiconductor 121. A conductive via V may be formed within the light emitting structure such that it penetrates the first conductive semiconductor layer 123 and the active layer 122, so as to be connected to the second conductive semiconductor layer 121. Also, a second contact layer 170 may be formed between the first conductive semiconductor layer 123 and the conductive substrate 140 and extend from the conductive via V. A current interruption region 160 may be formed in the first conductive semiconductor layer 123 adjacent to the conductive via V.

Unlike the embodiment illustrated in FIGS. 1 and 2, in an embodiment of the present inventive concept, the conductive substrate 140 is electrically connected to the first conductive semiconductor layer 123, rather than to the second conductive semiconductor layer 121. Thus, the first contact layer 130 is not necessarily required, and in this case, the first conductive semiconductor layer 130 and the conductive substrate 140 may be in direct contact with each other.

The via V connected to the second conductive semiconductor layer 121 penetrates the active layer 122, the first conductive semiconductor layer 123, and the first contact layer 130, so as to be connected to the second conductivity-type conductor layer 170. The second contact layer 170 may include an electrical connection portion extending in a lateral direction of the light emitting structure 120 from the conductive via V and being exposed to the outside. An electrode pad 121a may be formed on the electrical connection portion.

In this case, an insulator 151 and 152 may be formed to electrically separate the second contact layer 170 and the conductive via V from other layers including the active layer 122, the first conductive semiconductor layer 123, the first contact layer 130, and the conductive substrate 140. The insulator may include a first insulator 151 for separating the conductive via V from the active layer 122, the first conductive semiconductor layer 123, and the second contact layer 130 and a second insulator 152 for separating the second contact layer 170 from the conductive substrate 140.

In an embodiment of the present inventive concept, the current interruption region 160 may be formed in at least one of the first and second conductive semiconductor layers 123 and 121, and may be formed in a region adjacent to the conductive via V to expand a current flow region. The current interruption region 160 may be configured as an insulating region formed through ion implantation or by oxidizing portions of the first and second conductive semiconductor layers 123 and 121.

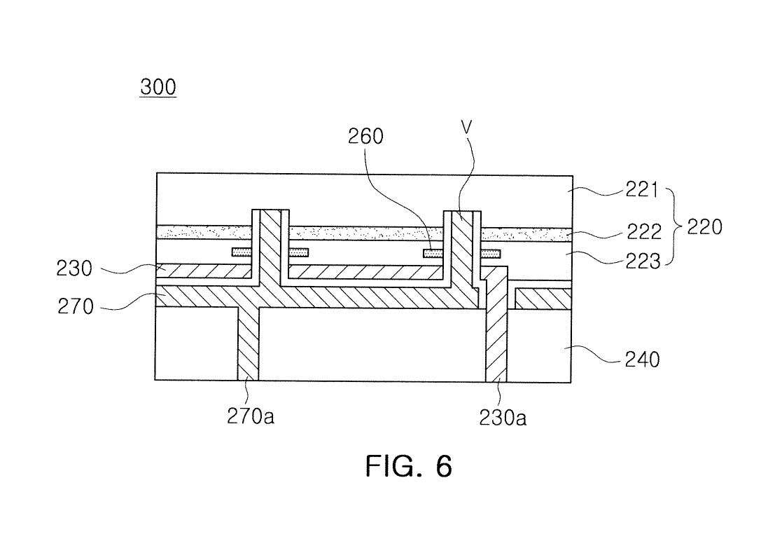

FIG. 6 is a perspective view illustrating a section of a semiconductor light emitting device according to an embodiment of the present inventive concept;

With reference to FIG. 6, a semiconductor light emitting device 300 may include a light emitting structure 220 formed on a substrate 240 and a first contact layer 230 formed between the light emitting structure 220 and the substrate 240. The light emitting structure 220 may include a first conductive semiconductor layer 223, an active layer 222, and a second conductive semiconductor layer 221. A conductive via V may be formed within the light emitting structure 220 and penetrate the first contact layer 230, the first conductive semiconductor layer 223 and the active layer 222, so as to be connected to the second conductive semiconductor layer 221. A current interruption region 260 may be formed to be adjacent to the conductive via V in the light emitting structure 220.

The first conductive semiconductor layer 230 may include a first electrical connection portion 230a extending in a direction parallel to the substrate 240 and being exposed to the outside. Also, the semiconductor light emitting device 300 may further include a second contact layer 270 extending from the conductive via V and formed between the first contact layer 230 and the substrate 240. The second contact layer 270 may include a second electrical connection portion 270a extending in the direction parallel to the substrate 240 and being exposed to the outside.

In an embodiment of the present inventive concept illustrated in FIG. 6, the substrate 240 may be an insulating substrate or a conductive substrate. For example, when the substrate 240 is an insulating substrate made of a material such as ceramic, sapphire, or the like, the first and second electrical connection portions 230a and 270a may be electrically separated by the substrate 240. Alternatively, when the substrate 240 is a conductive substrate, an insulator (not separately shown) may be interposed in order to electrically separate the first and second electrical connection portions 230a and 270a extending in the direction parallel to the substrate 240.

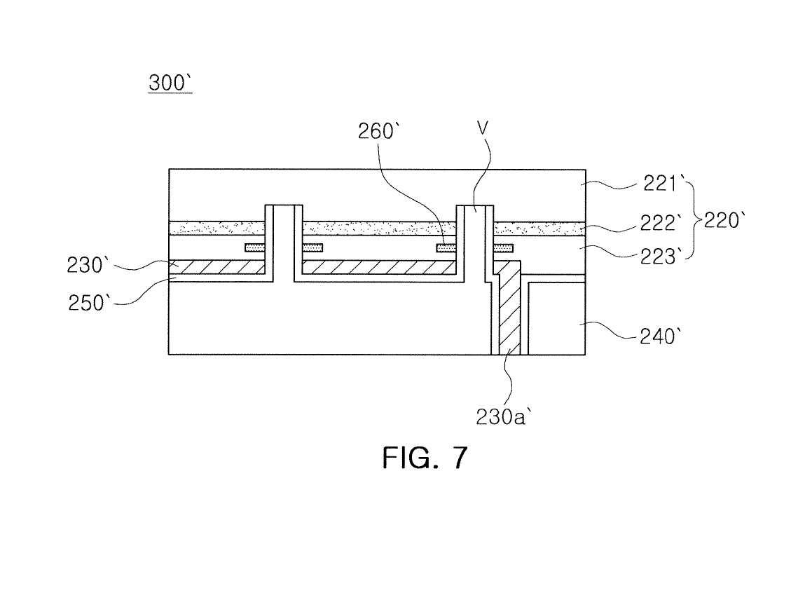

FIG. 7 is a schematic view illustrating a section of a semiconductor light emitting device according to a modification of the embodiment of the present inventive concept illustrated in FIG. 6.

With reference to FIG. 7, unlike the embodiment illustrated in FIG. 6, a semiconductor light emitting device 300′ according to an embodiment of the present inventive concept does not have the second contact layer 270, and a conductive via V extends directly from a substrate 240′ so as to be connected to a second conductive semiconductor layer 221′. In an embodiment of the present inventive concept, the substrate 240′ may be a conductive substrate, and an insulator 250′ may be formed to electrically separate the substrate 240′ from a first contact layer 230′. With reference to FIG. 7, the semiconductor light emitting device 300′ may include a light emitting structure 220′ formed on the substrate 240′. The light emitting structure 220′ may include a first conductive semiconductor layer 223′, an active layer 222′, and the second conductive semiconductor layer 221′.

As the substrate 240′, for example, a conductive substrate made of a material including any one of Au, Ni, Al, Cu, W, Si, Se, and GaAs may be used, and in this case, the insulator 250′ to electrically separate the substrate 240′ and the first contact layer 230′ may be interposed therebetween. In an embodiment of the present inventive concept, the substrate 240′ may serve as a terminal, namely, a second electrical connection portion, for applying an electrical signal to the second conductive semiconductor layer 221′ through the conductive via V.

In the case of the structure in which the electrode is exposed from a lower portion of a device like the semiconductor light emitting device illustrated in FIGS. 6 and 7, the light emitting device can be directly mounted on a substrate, a lead frame, or the like. Since a connection structure such as a conductive wire, or the like, is not used, advantageous effects in terms of reliability, light extraction efficiency, process convenience, and the like, can be achieved.

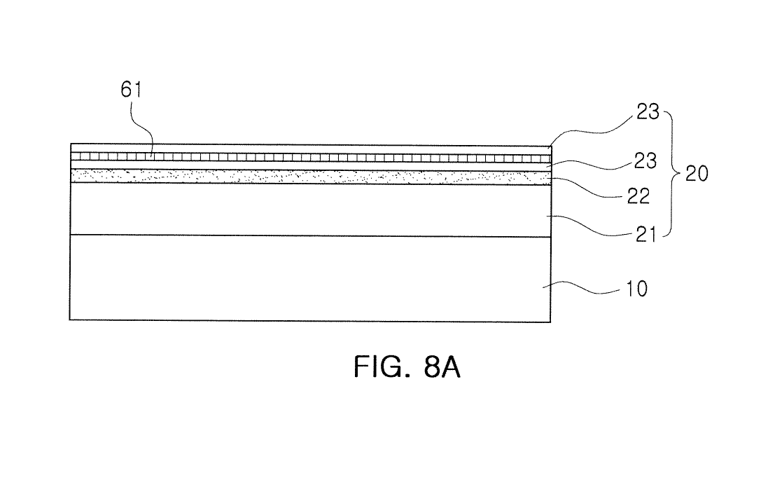

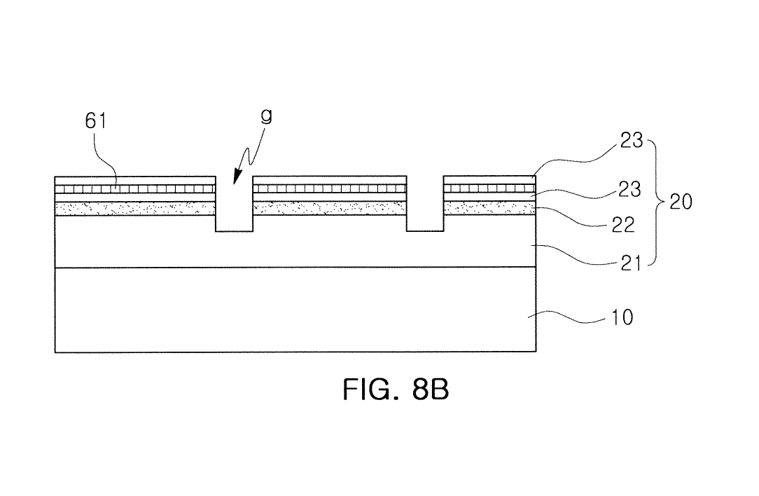

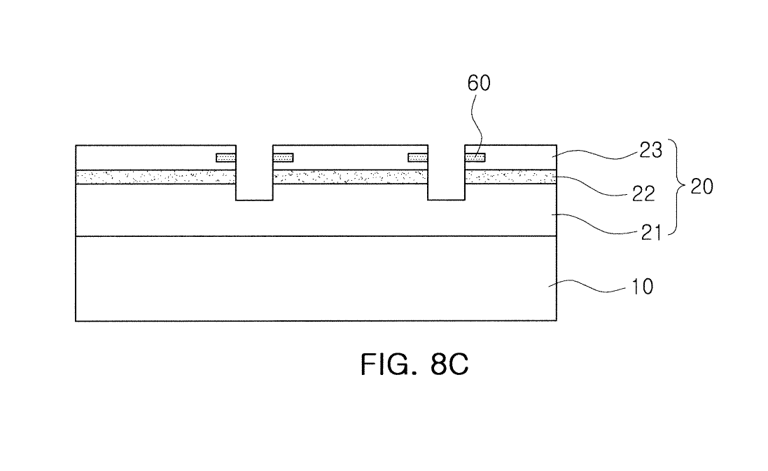

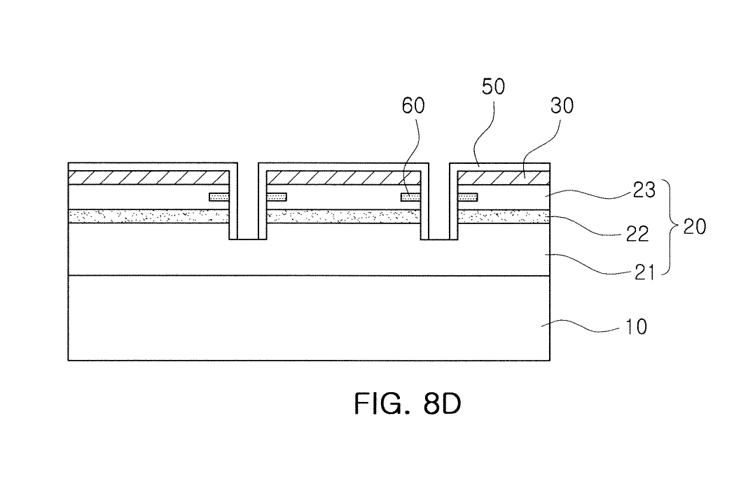

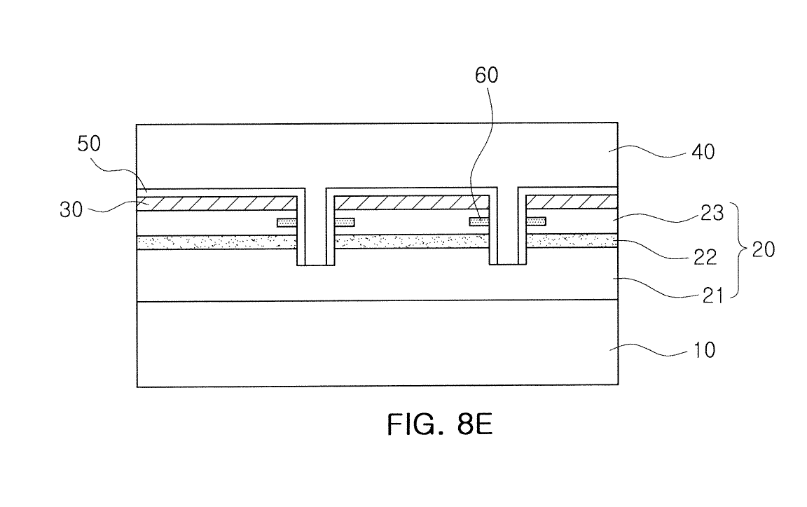

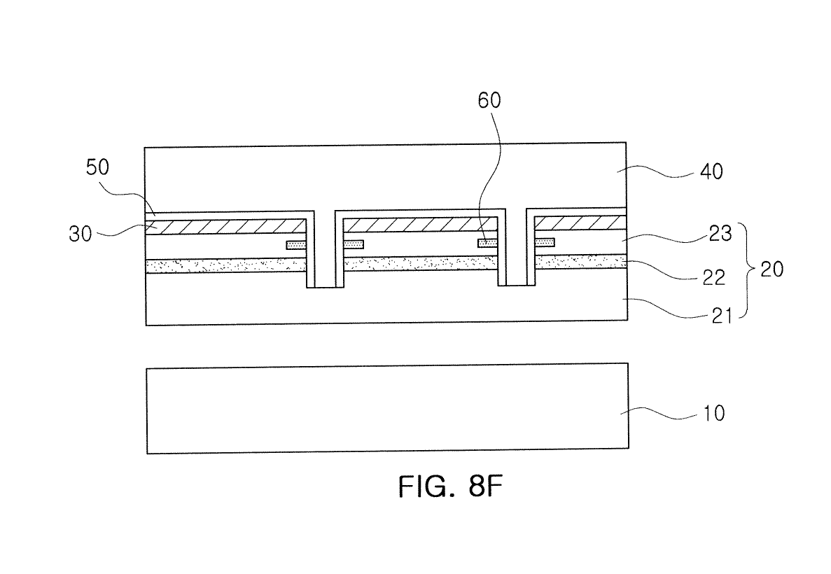

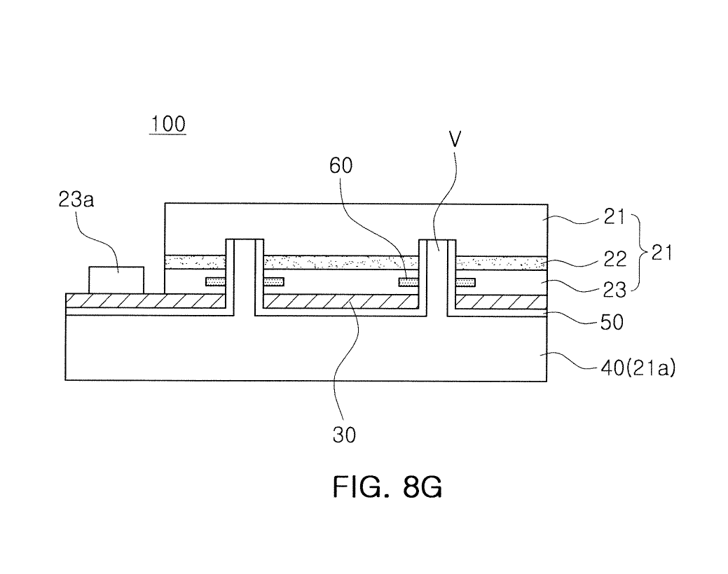

FIGS. 8A to 8G are sectional views sequentially illustrating a method of fabricating a semiconductor light emitting device according to an embodiment of the present inventive concept. Specifically, the method corresponds to processes for fabricating the semiconductor light emitting device having the structure illustrated in FIG. 1.

The method of fabricating a semiconductor light emitting device according to an embodiment of the present inventive concept may include a step of forming the light emitting structure 20 including the first conductive semiconductor layer 23, the active layer 22, and the second conductive semiconductor layer 21 on a semiconductor growth substrate 10, a step of forming the current interruption region 60 (see FIG. 8C) in a portion of the light emitting structure 20, a step of forming a recess g (see FIG. 8B) in the light emitting structure 20, a step of forming the first contact layer 30 in the light emitting structure 20, a step of forming the insulator 50 to cover an upper portion of the first contact layer 30 and the recess g, a step of forming the conductive via V within the recess g, a step of forming the conductive substrate 40 such that it is connected to the conductive via V, and a step of removing the semiconductor growth substrate 10.

First, as shown in FIG. 8A, the light emitting structure 20 may be formed by sequentially growing the second conductive semiconductor layer 21, the active layer 22, and the first conductive semiconductor layer 23 from the semiconductor growth substrate 10 by using a semiconductor layer growth process such as MOCVD, MBE, HVPE, or the like. The light emitting structure 20 may be made of a nitride semiconductor having a composition of AlₓIn_{y}Ga_{(1-x-y)N (}0≦x≦1, 0≦y≦1, 0≦x+y≦1). At least one of the first and second conductive semiconductor layers 23 and 21 may include a AlₓIn_{y}Ga_{(1-x-y)}N (0<x≦1, 0≦y≦1, 0≦x+y≦1) layer 61, e.g., an AlInN layer, for forming the current interruption region 60 (see FIG. 8C) by oxidization.

As the semiconductor growth substrate 10, a substrate made of a material such as SiC, MgAl₂O₄, MgO, LiAlO₂, LiGaO₂ GaN, or the like, may be used. In this case, sapphire is a crystal having Hexa-Rhombo R3c symmetry, of which lattice constants in c-axis and a-axis directions are 13.001 Å and 4.758 Å, respectively. The sapphire crystal has a C (0001) plane, an A (1120) plane, an R (1102) plane, and the like. In this case, a nitride thin film can be relatively easily formed on the C plane of the sapphire crystal. Because sapphire crystal is stable at high temperatures, sapphire crystal is commonly used as a material for a nitride growth substrate. Although not separately illustrated, a buffer layer may be formed between the light emitting structure 20 and the semiconductor growth substrate 10, and here, the buffer layer is employed as an undoped semiconductor layer made of a nitride, or the like, to alleviate a lattice defect in the light emitting structure grown thereon.

Next, as shown in FIG. 8B, the recess g may be formed in the light emitting structure 20. The recess g is provided to form a conductive via connected to the second conductive semiconductor layer 21 by filling a conductive material therein in a follow-up process. The recess g penetrates the first conductive semiconductor layer 23 and the active layer and has a configuration in which the first conductive semiconductor layer 23 is exposed.

In an embodiment of the present inventive concept, in forming the recess g, a portion of the first conductive semiconductor layer 23 is removed. In a different embodiment of the present inventive concept, the first conductive semiconductor layer 23 may not be removed and an upper surface thereof may form a lower surface of the recess g. The recess g formation process may be performed by using an etching process, e.g., ICP-RIE, or the like.

Thereafter, as shown in FIG. 8C, the AlₓIn_{y}Ga_{(1-x-y)}N (0<x≦1, 0≦y≦1, 0≦x+y≦1) layer 61 is selectively oxidized to form the current interruption region 60. For example, when the AlInN layer is oxidized, the current interruption region 60 may be formed to have a composition of AlInON, and the oxidized region forms an electrically insulated region. The oxidized depth, for example, the size of the current interruption region 60, may be appropriately adjusted through an oxidization time, an oxidization temperature, or the like.

The current interruption region 60 may alleviate a current concentration phenomenon due to a conductive via subsequently formed in the recess g to enhance current spreading efficiency, and accordingly, a light output and light uniformity of the semiconductor light emitting device can be improved.

Then, as shown in FIG. 8D, the first contact layer 30 may be formed on the light emitting structure 20, and the insulator 50 may be formed to cover an inner surface of the recess g formed in the light emitting structure 20 and an upper surface of the second contact layer 30 and expose the second conductive semiconductor layer 21 from a lower surface within the recess g.

The first contact layer 30 may be formed to include a material such as Ag, Ni, Al, Rh, Pd, Ir, Ru, Mg, Zn, Pt, Au, or the like, in realizing a light reflection function and an ohmic-contact function with the first conductive semiconductor layer 23. A process such as sputtering, deposition, or the like, may be appropriately used. Also, the insulator 50 may be formed by depositing a material such as SiO₂, SiOₓN_{y}, SₓN_{y}, or the like.

In an embodiment of the present inventive concept illustrated in FIG. 8D, the first contact layer 30 is illustrated as being formed on the light emitting structure 20 after the recess g is formed, but the present inventive concept is not limited thereto. Before the recess g is formed, the first contact layer 30 may be formed on an upper surface of the light emitting structure 20 illustrated in FIG. 8A, and then, the recess g may be formed such that the second conductive semiconductor layer 21 is exposed.

Thereafter, as shown in FIG. 8E, a conductive material is formed within the recess g and on the insulator 50 to form the conductive via V and the conductive substrate 40, respectively. Accordingly, the conductive substrate 40 is connected to the conductive via V connected to the second connectivity type semiconductor layer 21.

The conductive substrate 40 may be made of a material including any one of Au, Ni, Al, Cu, W, Si, Se, and GaAs, and may be appropriately formed through a process such as plating, sputtering, deposition, or the like. In this case, the conductive via V and the conductive substrate 40 may be made of the same material. Alternatively, according to circumstances, the conductive via V may be made of a material different from that of the conductive substrate 107, and the conductive via V and the conductive substrate 107 may be formed through separate processes. For example, after the conductive via V is formed through a deposition process, the conductive substrate 40 may be previously formed and bonded to the light emitting structure.

And then, as shown in FIG. 8F, the semiconductor growth substrate 10 is removed from the light emitting structure 20. Here, the semiconductor growth substrate 10 may be removed by using a process such as laser lift-off, chemical lift-off, or the like. In this case, as the semiconductor growth substrate 10 is removed, the second conductive semiconductor layer 21 may be exposed. Alternatively, when a buffer layer (not separately shown) has been interposed between the semiconductor growth substrate 10 and the light emitting structure 20, the buffer layer may be exposed.

Also, although not shown in detail, depressions or protrusions may be formed on the surface exposed as the semiconductor growth substrate 10 is removed, e.g., on the second conductive semiconductor layer 21 or the buffer layer (not separately shown) to enhance light extraction efficiency.

FIG. 8G shows the state in which the semiconductor growth substrate 10 was removed, and the remaining structure is rotated by 180° from the state of FIG. 8F so as to be illustrated. With reference to FIG. 8G, portions of the second conductive semiconductor layer 21, the active layer 22, and the first conductive semiconductor layer 23 of the light emitting structure 20, which are exposed after the semiconductor growth substrate 10 has been removed, are removed to expose the first contact layer 30. The first electrode 23a may be formed on the exposed first contact layer 30 to apply an external electrical signal to the first conductive semiconductor layer 23.

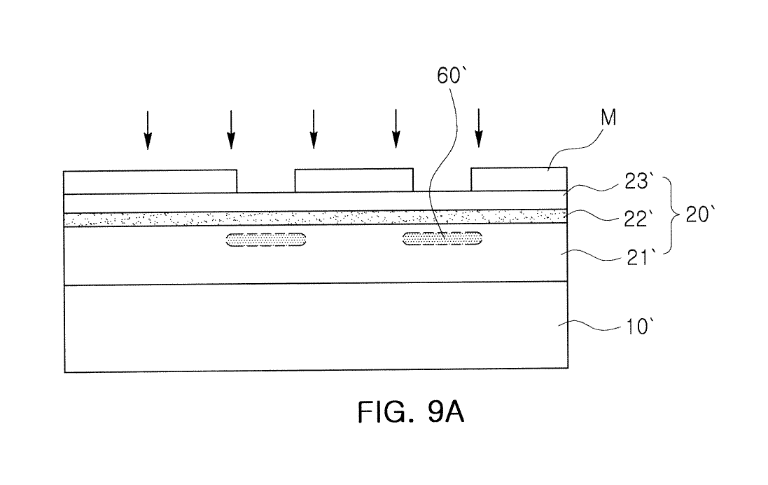

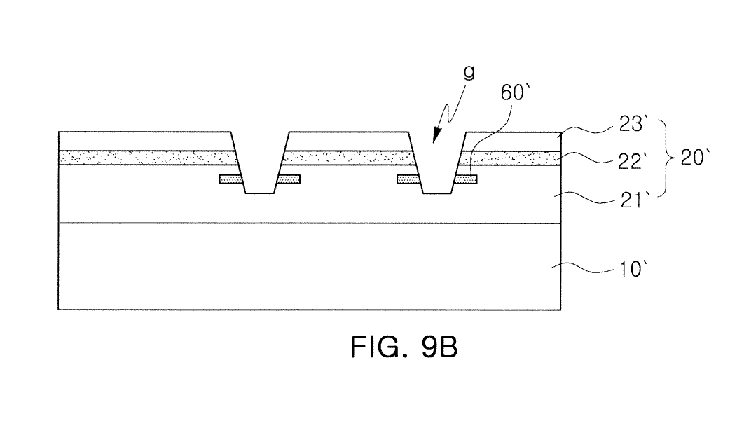

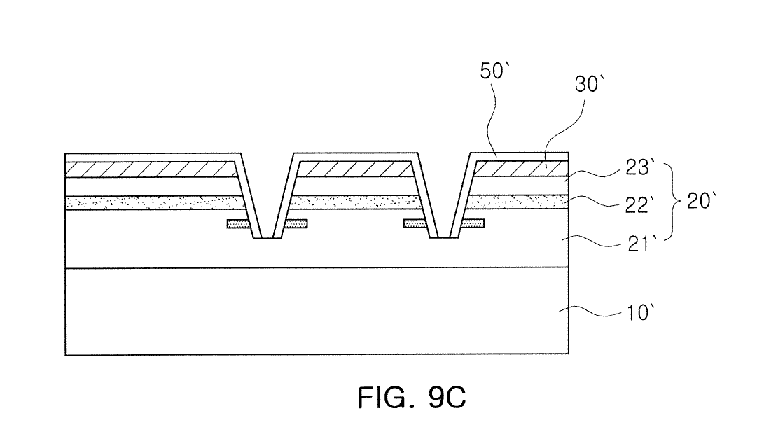

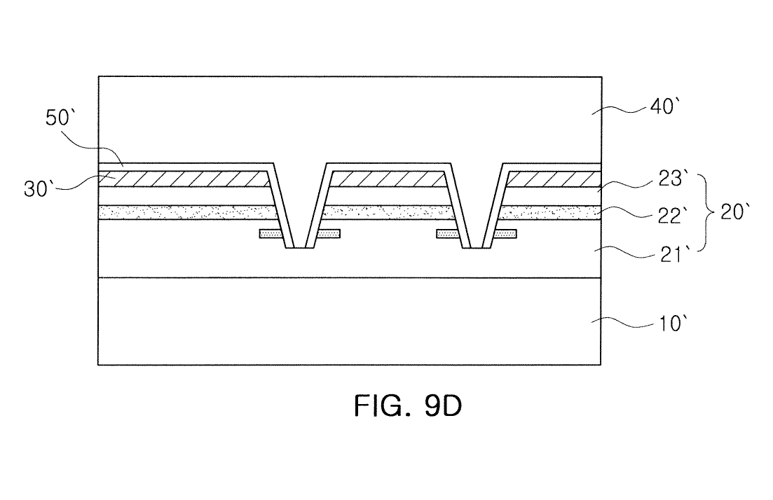

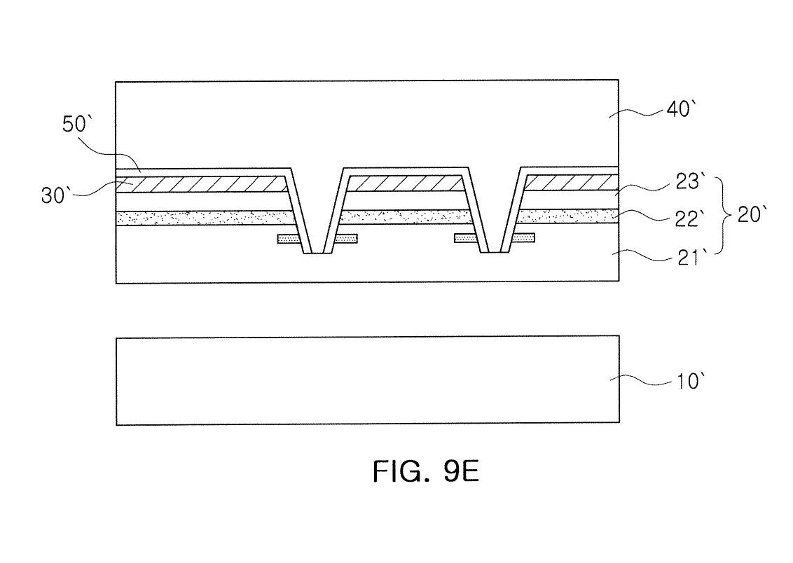

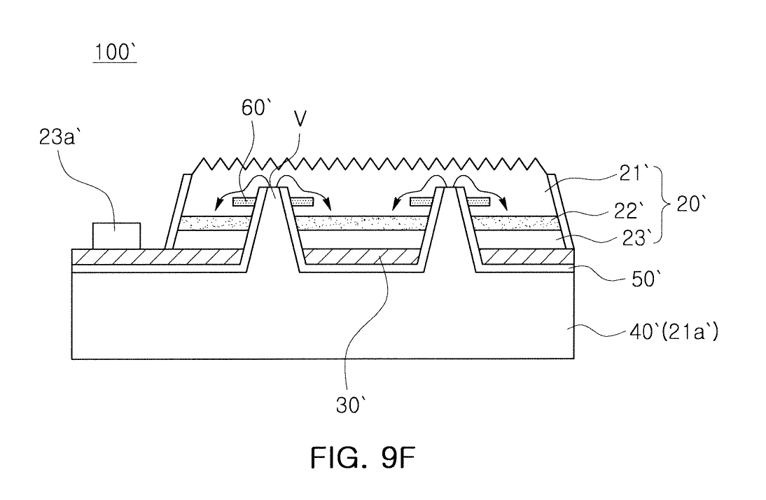

FIGS. 9A to 9F are sectional views sequentially illustrating a method of fabricating a semiconductor light emitting device according to another embodiment of the present inventive concept. Specifically, the method corresponds to the processes for fabricating the semiconductor light emitting device 100′ having the structure illustrated in FIG. 3.

The method of fabricating a semiconductor light emitting structure according to an embodiment of the present inventive concept illustrated in FIGS. 9A-9F, includes a step of forming the light emitting structure 20′ including the first conductive semiconductor layer 23′, the active layer 22′, and the second conductive semiconductor layer 21′ on the semiconductor growth substrate 10′, a step of forming the current interruption region 60′ in a portion of the light emitting structure 20′, a step of forming the recess g (see FIG. 9B) in the light emitting structure 20′, a step of forming the first contact layer 30′ on the light emitting structure 20′, a step of forming the insulator 50′ (see FIG. 9C) to cover the upper portion of the first contact layer 30′ and the recess g, a step of forming the conductive via V (see FIG. 9F) within the recess g, a step of forming the conductive substrate 40′ (see FIG. 9D) such that it is connected to the conductive via V, and a step of removing the semiconductor growth substrate 10′.

In comparison to the method of fabricating the semiconductor light emitting device illustrated in FIGS. 8A to 8G, the method illustrated in FIGS. 9A-9F according to an embodiment of the present inventive concept is mainly different in a method of forming the current interruption region 60′.

First, as shown in FIG. 9A, the light emitting structure 20′ may be formed by sequentially growing the second conductive semiconductor layer 21′, the active layer 22′, and the first conductive semiconductor layer 23′ on the semiconductor growth substrate 10′. The process of forming the light emitting structure 20′ has been already described above with reference to FIG. 8A, so a detailed description thereof will be omitted.

In an embodiment of the present inventive concept, a mask M is formed on the light emitting structure 20′, and ions may be implanted to regions opened through the mask M to form the current interruption region 60′ in at least one of the first and second conductive semiconductor layers 23′ and 21′.

The mask M may be formed of a photoresist pattern exposing a portion of the upper surface of the first conductive semiconductor layer 23′. The photoresist has properties that a photosensitive portion is not dissolved (negative type) by a developer (i.e., a developing solution) by light irradiation or dissolved (positive type). The photoresist is obtained by dissolving a photosensitive component (generally, organic polymer) in an organic solvent.

Ion implantable elements such as H, 2H, 3H, He, N, C, Ar, Zn, P, Ti, Zn, or the like, may be ion-implanted to the light emitting structure 20′ with the mask M formed thereon. Accordingly, the current interruption region 60′, e.g., an insulating region, may be formed in at least one of the first and second conductive semiconductor layers 23′ and 21′ of the light emitting structure 20′ exposed through the opening regions of the mask M. In this case, the depth of the ion implanted region, or the like, may be precisely adjusted through an acceleration voltage, or the like.

Next, as shown in FIG. 9B, the mask M is removed, and the recess g may be formed in the light emitting structure 20′ in which the current interruption region 60′ is formed. The recess g is a region for forming the conductive via V later, and here, the recess g may be formed to have a width narrowed toward the semiconductor growth substrate 10′ and have a diameter smaller than the current interruption region 60′ formed through ion implantation. For example, the recess g may be formed within a range in which the current interruption region 60′ is not entirely eliminated.

And then, as shown in FIG. 9C, the first contact layer 30′ is formed on the first conductive semiconductor layer 23′ of the light emitting structure 20′. A material such as SiO₂, SiOₓN_{y}, SiₓN_{y}, or the like, is deposited to form the insulator 50′ such that the insulator 50′ covers the first contact layer 30′ and inner side walls of the recess g. The insulator 50′ may have an omni-directional reflector (ODR) or a Bragg reflector (DBR) structure to perform a light reflection function. Also, like the foregoing embodiments, the first contact layer 30′ may be formed in a previous step before the recess g is formed.

Thereafter, as shown in FIG. 9D, a conductive material is formed within the recess g and on the insulator 50′ to form the conductive via V (see FIG. 9F) and the conductive substrate 40′. Accordingly, the conductive substrate 40′ is connected to the conductive via V connected to the second conductive semiconductor layer 21′.

And then, as shown in FIG. 9E, the semiconductor growth substrate 10′ is removed from the light emitting structure 20′. Here, the semiconductor growth substrate 10′ may be removed by using a process such as laser lift-off, chemical lift-off, or the like.

FIG. 9F shows the state in which the semiconductor growth substrate 10′ was removed, and the remaining structure is rotated by 180° from the state of FIG. 9E so as to be illustrated. With reference to FIG. 9E, a depression and protrusion structure may be formed on the second conductive semiconductor layer 21′ of the light emitting structure 20′ exposed as the semiconductor growth substrate 10′ was removed.

Also, portions of the second conductive semiconductor layer 21′, the active layer 22′, and the first conductive semiconductor layer 23′ of the light emitting structure 20′ may be removed to expose the first contact layer 30′. A first electrode 23a′ may be formed on the exposed first contact layer 30′ to apply an external electrical signal to the first conductive semiconductor layer 23′.

In the case of the method of fabricating a light emitting device according to an embodiment of the present inventive concept illustrated in FIGS. 9A-9F, since the insulating region is formed in the first or second conductive semiconductor layer adjacent to the conductive via by using oxidation, ion implantation, or the like, during the fabrication process of the semiconductor light emitting device, a semiconductor light emitting device having enhanced light output and light uniformity can be fabricated.

Meanwhile, FIGS. 8A through 8G and 9A through 9F illustrate the fabrication processes based on semiconductor light emitting devices according to the embodiment of the present inventive concept illustrated in FIGS. 1 and 2 and a modification thereof. But, in the case of the semiconductor light emitting device according to the embodiments illustrated in FIGS. 5 and 6, only the positions of the first and second contact layers are different in comparison to the embodiment illustrated in FIGS. 1 and 2, so the processes illustrated in FIGS. 8A through 8G and 9A through 9F may be appropriately altered to be applied.

As set forth above, according to an embodiment of the present inventive concept, the semiconductor light emitting device having increased current spreading effect and enhanced light output can be provided.

According to another embodiment of the present inventive concept, the semiconductor light emitting device having enhanced light uniformity and light output can be fabricated by using a simple process.

Although a few exemplary embodiments of the present inventive concept have been shown and described, the present inventive concept is not limited to the described exemplary embodiments. Instead, it would be appreciated by those skilled in the art that changes may be made to these exemplary embodiments without departing from the principles and spirit of the inventive concept, the scope of which is defined by the appended claims and their equivalents.

What is claimed is:

1. A semiconductor light emitting device, comprising:
a conductive substrate;
a light emitting structure disposed on the conductive substrate and including a first conductive semiconductor layer, an active layer, and a second conductive semiconductor layer;
a first contact layer disposed between the conductive substrate and the first conductive semiconductor layer;
a conductive via disposed to extend from the conductive substrate and penetrating the first contact layer, the first conductive semiconductor layer, and the active layer so as to be connected to the second conductive semiconductor layer; and
a current interruption region disposed in a region adjacent to the conductive via in the light emitting structure.

2. The semiconductor light emitting device of claim 1, wherein the current interruption region is disposed in at least one of the first and second conductive semiconductor layers of the light emitting structure.

3. The semiconductor light emitting device of claim 2, wherein the current interruption region is an insulating region including an oxidized portion of at least one of the first and second conductive semiconductor.

4. The semiconductor light emitting device of claim 2, wherein the current interruption region is an insulating region including an ion implanted portion of at least one of the first and second conductive semiconductor layers.

5. The semiconductor light emitting device of claim 1, wherein at least one of the first and second conductive semiconductor layers includes an AlₓIn_{y}Ga_{z}N layer (0<x≦1, 0≦y≦1, 0≦z≦1).

6. The semiconductor light emitting device of claim 5, wherein the current interruption region is made of AlInON.

7. The semiconductor light emitting device of claim 1, wherein the current interruption region is disposed in at least a portion of an area surrounding the conductive via.

8. The semiconductor light emitting device of claim 1, further comprising an insulator to electrically separate the conductive substrate from the first contact layer, the first conductive semiconductor layer, and the active layer.

9. The semiconductor light emitting device of claim 1, wherein a lateral side of the light emitting structure is sloped.

10. The semiconductor light emitting device of claim 1, wherein the conductive via is connected to the second conductive semiconductor layer.

11. A method of fabricating a semiconductor light emitting device, the method comprising steps of:
forming a light emitting structure by sequentially growing a second conductive semiconductor layer, an active layer, and a first conductive semiconductor layer on a semiconductor growth substrate;
forming a current interruption region in a portion in the light emitting structure;
forming a recess penetrating the first conductive semiconductor layer and the active layer and exposing the second conductive semiconductor layer;
forming a first contact layer on the light emitting structure;
forming an insulator to cover an upper portion of the first contact layer and a side wall of the recess;
forming a conductive material within the recess and on the insulator to form a conductive via connected to the second conductive semiconductor layer;
forming a conductive substrate on the insulator such that the conductive substrate is connected to the conductive via; and
removing the semiconductor growth substrate from the light emitting structure.

12. The method of claim 11, wherein the current interruption region is formed in at least one of the first and second conductive semiconductor layers of the light emitting structure.

13. The method of claim 12, wherein the current interruption region is formed by oxidizing a portion of at least one of the first and second conductive semiconductor layers.

14. The method of claim 11, wherein the current interruption region is formed in a portion adjacent to the conductive via.

15. The method of claim 11, wherein the current interruption region is formed by performing ion implantation.

16. A semiconductor light emitting device, comprising:
a conductive substrate;
a light emitting structure disposed on the conductive substrate and including a first conductive semiconductor layer, an active layer, and a second conductive semiconductor layer;
a first contact layer and a second contact layer, disposed between the conductive substrate and the first conductive semiconductor layer;
a conductive via disposed to extend from the second contact layer and penetrating the first contact layer, the first conductive semiconductor layer, and the active layer so as to be connected to the second conductive semiconductor layer; and
a current interruption region disposed in a region adjacent to the conductive via in the light emitting structure.

17. The semiconductor light emitting device of claim 16, wherein the second contact layer and the conductive via are electrically separated from the active layer, the first conductive semiconductor layer, the first contact layer, and the conductive substrate.
